(19) United States
(12) Patent Application Publication
(10) Pub. No.: US 2017/0174855 A1
(43) Pub. Date: Jun. 22, 2017

(54) SUPER-HYDROPHOBIC SURFACE BY CHEMICALLY MODIFIED BLOCK COPOLYMER GENERATED NANO-STRUCTURES

(71) Applicants: Erika Yang, Livermore, CA (US); Kai Chun Lin, Fremont, CA (US)

(72) Inventors: Erika Yang, Livermore, CA (US); Kai Chun Lin, Fremont, CA (US)

(21) Appl. No.: 15/096,289

(22) Filed: Apr. 12, 2016

Related U.S. Application Data
(60) Provisional application No. 62/270,024, filed on Dec. 20, 2015.

(51) Int. Cl. C08J 7/12; B05D 1/00; H01J 37/32

(52) U.S. Cl. CPC C08J 7/123; H01J 37/32009; B05D 1/005; H01J 37/3244; C08J 2383/10; C08J 2353/00; H01J 2237/334

(57) ABSTRACT

The embodiments disclose a method of using a molecular self-assembly of a predetermined spherical or cylindrical block copolymer (BCP) to create a nano-scale dot array pattern, transferring the BCP pattern into a chromium (Cr) hard mask layer, and then into a substrate. The patterned substrate is chemically modified with a predetermined self-assembled monolayer (SAM) with a hydrophobic functional group to form a super-hydrophobic surface.

### BRIEF DESCRIPTION OF THE DRAWINGS

FIG. 1 shows a block diagram of an overview of creating a super-hydrophobic surface by chemically modified nanostructures, fabricated through molecular self-assembly of block copolymer (BCP) and plasma etching.

FIG. 2A shows a block diagram of an overview flow chart of creating a super-hydrophobic surface through molecular self-assembly of block copolymer of one embodiment.

FIG. 2B shows a block diagram of an overview flow chart of creating a super-hydrophobic surface through molecular self-assembly of block copolymer and plasma etch of one embodiment.

FIG. 2C shows a block diagram of an overview flow chart of creating a super-hydrophobic surface through chemically modified nanostructures of one embodiment.

FIG. 3A shows for illustrative purposes only an example of chemically modified BCP-generated nanostructure of one embodiment.

FIG. 3B shows for illustrative purposes only an example of plasma etch process of one embodiment.

FIG. 4 shows for illustrative purposes only an example of water contact angle (CA) change after substrate patterning of one embodiment.

FIG. 5 shows for illustrative purposes only an example of water contact angle (CA) change after chemically modified BCP-generated nanostructures of one embodiment.

### DETAILED DESCRIPTION OF THE INVENTION

In a following description, reference is made to the accompanying drawings, which form a part hereof, and in which is shown by way of illustration a specific example in which the invention may be practiced. It is to be understood that other embodiments may be utilized and structural changes may be made without departing from the scope of the present invention.

### General Overview

It should be noted that the descriptions that follow, for example, in terms of chemically modified BCP patterned surface is described for illustrative purposes and the underlying system can apply to any number and multiple types stack. In one embodiment of the present invention, the chemically modified BCP-generated nanostructure surface can be configured using silicon, quartz, glass, or a metallic substrate. The chemically modified BCP-generated nanostructure surface for creating a super-hydrophobic surface can be configured to include vertically oriented cylindrical or spherical block copolymer and can be configured to include super-hydrophobic surface as a water-repellant material using the present invention.

The chemically modified nanostructure surface can be super-hydrophobic.

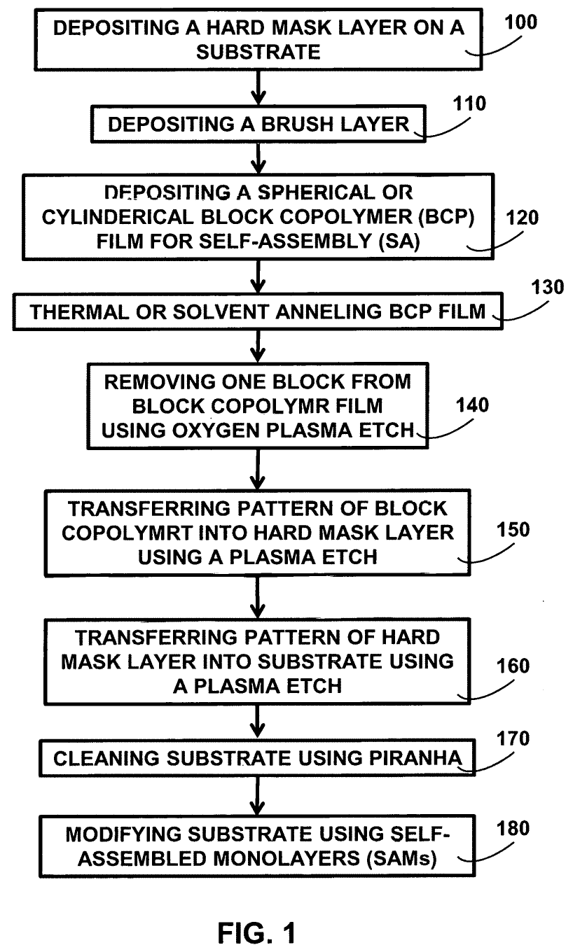

FIG. 1 shows a block diagram of an overview of chemically modified BCP-generated nanostructure surface of one embodiment. FIG. 1 shows a method to fabricate a super-hydrophobic surface for use as a water-repellant surface, that can be used in as good self-cleaning materials for many applications, such as solar panels, building glass, car windows, and street light covers.

FIG. 1 shows depositing a hard mask layer on a substrate 100. A brush layer 110 is chemically bonded into the substrate. Depositing a spherical or cylindrical block copolymer (BCP) 120 onto the brushed substrate. Then, the BCP coated substrate is thermal or solvent annealing for molecular self-assembly 130. After the self-assembly, an oxygen-based plasma etch is used for removing a first copolymer 140 to form a BCP dot array pattern on the substrate. A chlorine-based plasma etch process is used to transfer the BCP dot array pattern into the hard mask layer 150. A fluorine-based plasma etch process is used for etching the hard mask layer into the substrate to form many nano-pillars 160. The substrate is cleaned using a piranha solution 170, and then it is chemically modified with self-assembled monolayers (SAMs) 180. A super-hydrophobic surface with a water-repellant function is formed.

### Detailed Description

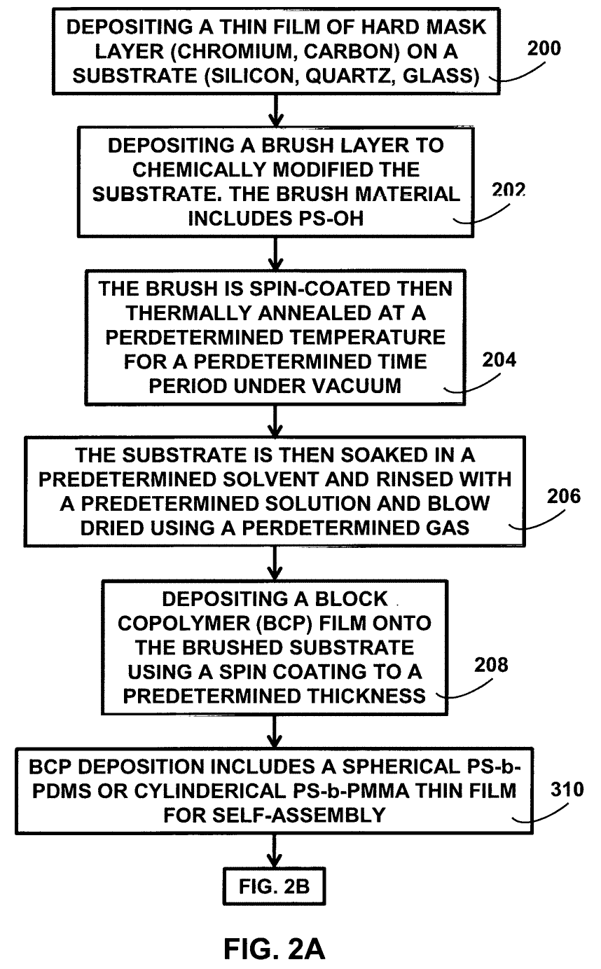

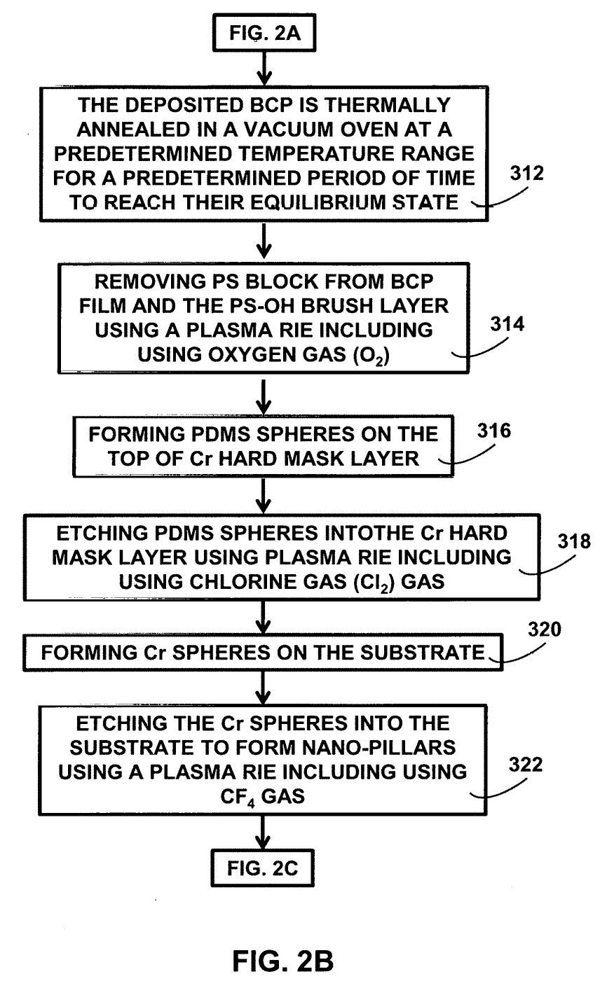

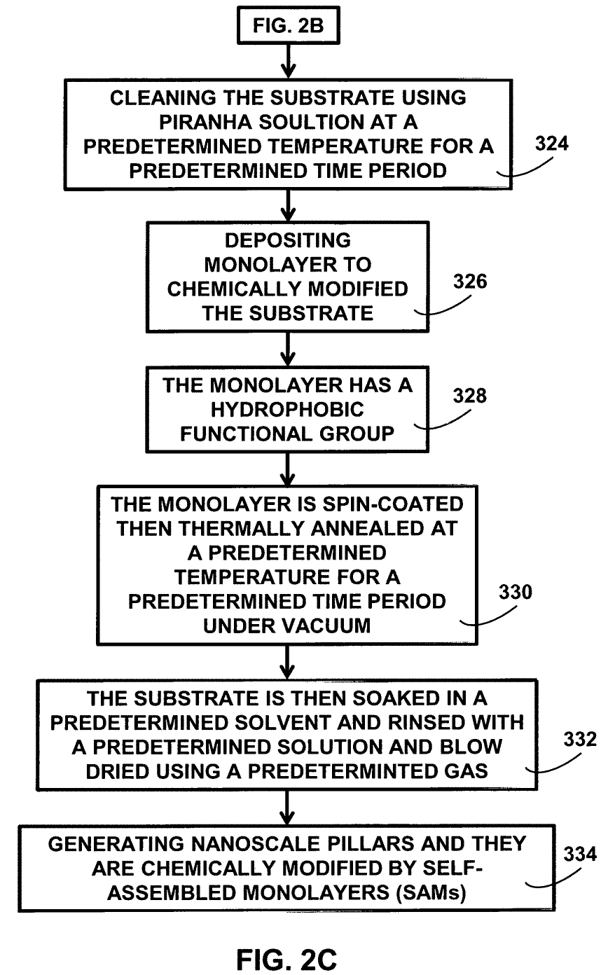

FIG. 2A shows a block diagram of an overview flow chart of creating a super-hydrophobic surface through molecular self-assembly of block copolymer of one embodiment.

FIG. 2A shows a substrate 200 made of materials including silicon, quartz, glass and other substrate materials that can be chemically modified. A hard mask layer including chromium (Cr) or carbon (C) is deposited on the substrate 202.

The brush including PS—OH is spin-coated then thermally annealed at a predetermined temperature for a predetermined time period under vacuum 204.

The substrate is then soaked in a predetermined solvent for a predetermined time period and rinsed with a predetermined solution and blow dried using a predetermined gas 206.

A thin film of block copolymer (BCP) is spin coated onto the brushed substrate to a predetermined thickness 208.

BCP deposition includes a spherical PS-b-PDMS or cylindrical PS-b-PMMA BCP film for self-assembly 310. The processing is described further in FIG. 2B.

FIG. 2B shows a block diagram of an overview flow chart of creating a super-hydrophobic surface through molecular self-assembly of block copolymer of one embodiment. FIG. 2B shows continuing from FIG. 2A. The deposited BCP is thermally annealed in a vacuum oven at a predetermined temperature range for a predetermined period of time to reach their equilibrium state 312.

Removing PS block from spherical PS-b-PDMS or PMMA block from cylindrical PS-b-PMMA BCP film using a plasma RIE including oxygen (O₂) gas 314.

PDMS spheres or PS hole matrix are formed on the top of Cr hard mask layer 316.

In case of using PDMS spheres, the next step is to etch PDMS spheres into the Cr hard mask layer using plasma RIE including Using chlorine (Cl₂) gas 318. The Cr spheres are formed on the substrate 320.

In case of using PS hole matrix, there is no need to deposit Cr hard layer underneath. The next step is to deposit Cr into the hole, and then do the Cr wet or dry life-off process. The Cr pillars are formed on the substrate.

The Cr spheres or pillars are used as etching hard mask to etch into the substrate to form nano-pillars using a plasma RIE including using CF₄ gas 322.

FIG. 2C shows a block diagram of an overview flow chart of creating a super-hydrophobic surface through chemically modified nanostructures of one embodiment. After CF₄ etch, the substrate is cleared using piranha solution at a predetermined temperature for a predetermined time period 324. The monolayer is used to chemically the substrate 326. The monolayer has a hydrophobic functional group 328. The monolayer is spin coated, and then thermally annealed at a predetermined temperature for a predetermined time period under vacuum 330. The substrate is then soaked in a predetermined solvent and rinsed with a predetermined solution and blow dried using a predetermined gas 332.

Finally, a super-hydrophobic surface is created by fabricating a nano pillar-array surface first, and then it is chemically modified by self-assembled monolayers with a hydrophobic functional group.

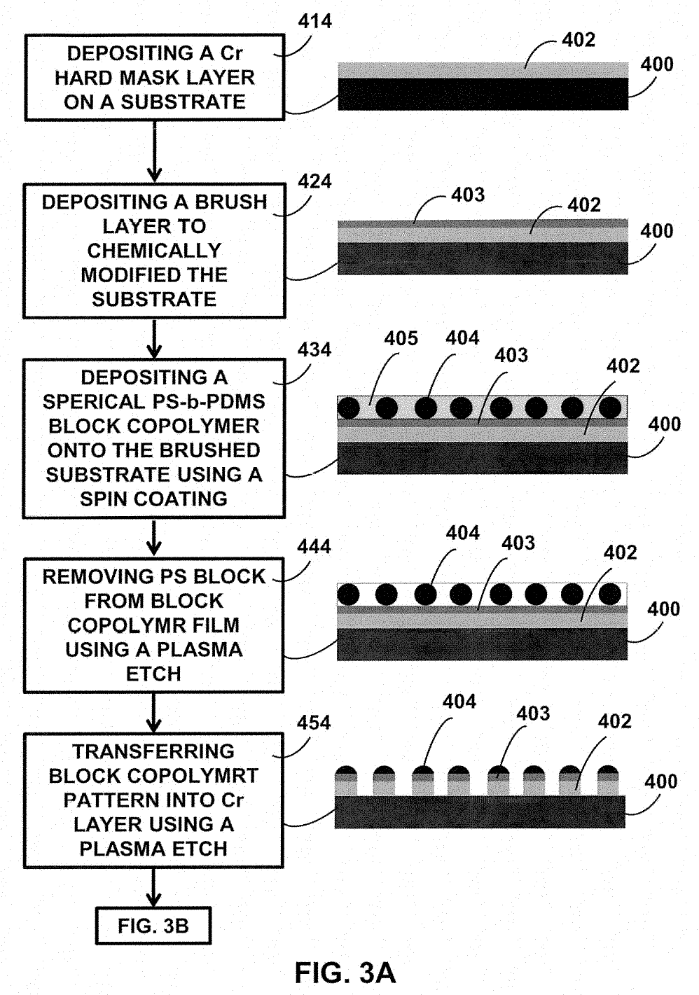

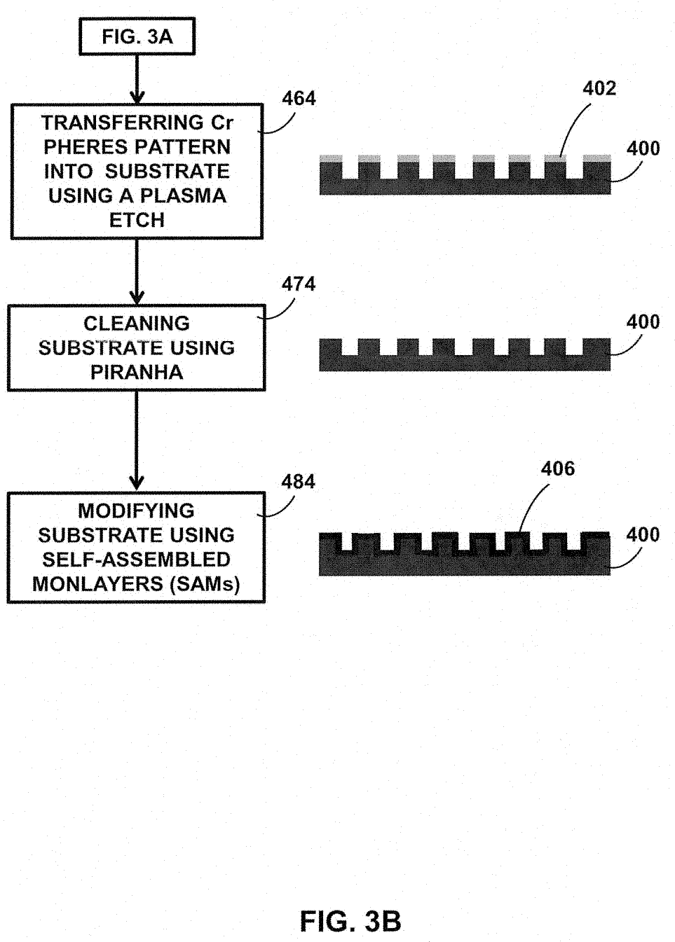

FIG. 3A shows for illustrative purposes only an example of fabricating a super-hydrophobic surface of one embodiment. FIG. 3A shows to deposit a chromium (Cr) hard mask layer 402 on a substrate 400. A substrate 400, including silicon, quartz, or glass 414.

The brush including PS—OH 403 is spin-coated then thermally annealed at a predetermined temperature for a predetermined time period under vacuum 424. The substrate is then soaked in a predetermined solvent for a predetermined time period and rinsed with a predetermined solution and blow dried using a predetermined gas.

A thin film of spherical PS-b-PDMS block copolymer (BCP) 404 is spin-coated onto the brushed substrate to a predetermined thickness 434. Removing PS block 405 from spherical PS-b-PDMS BCP film using a plasma RIE including oxygen (O₂) gas 444. Therefore, the PDMS spheres are formed on the top of Cr hard mask layer 402. The next step is to etch PDMS spheres into the Cr hard mask layer 402 using plasma RIE including Using chlorine (Cl₂) gas. The Cr spheres are formed on the substrate 454.

FIG. 3B shows for illustrative purposes only an example of plasma etch process of one embodiment. The Cr spheres 402 are used as etch hard mask to etch into the substrate 400 to form nano-pillars using a plasma RIE including using CF₄ gas. After CF₄ etch, the substrate 400 is cleared using piranha solution at a predetermined temperature for a predetermined time period 474. The monolayer 406 is used to chemically modify the substrate 400. The monolayer has a hydrophobic functional group. The monolayer is spin coated, and then thermally annealed at a predetermined temperature for a predetermined time period under vacuum. The substrate is then soaked in a predetermined solvent and rinsed with a predetermined solution and blow dried using N₂ gas. Finally, a super-hydrophobic surface is created by fabricating a nano pillar-array surface first, and then it is chemically modified by self-assembled monolayers with a hydrophobic functional group.

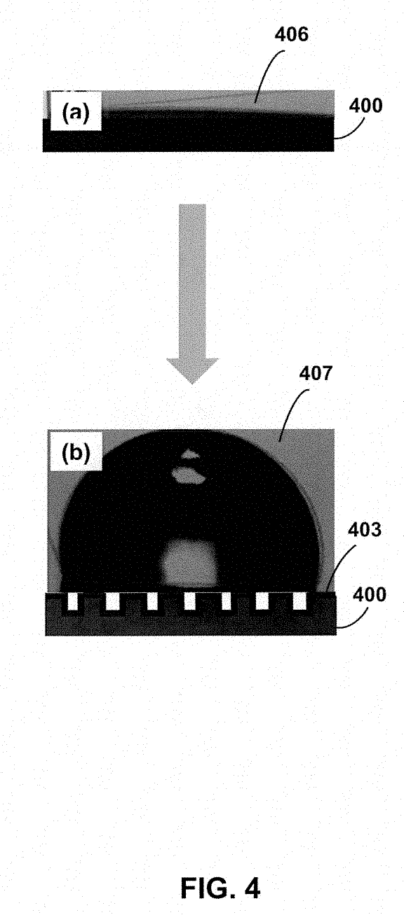

FIG. 4 shows for illustrative purposes only an example of creating a super-hydrophobic surface of one embodiment. FIG. 4 shows a contrast in the change of water contact angle (CA) from a silicon substrate. It shows super-hydrophilic when as it is, however after using the method invented here, the surface becomes super-hydrophobic.

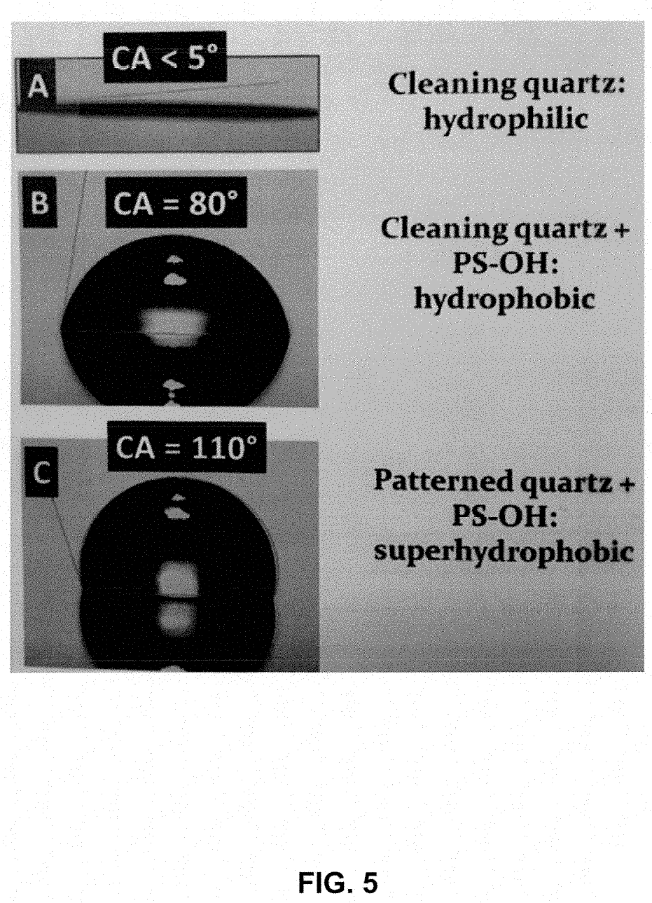

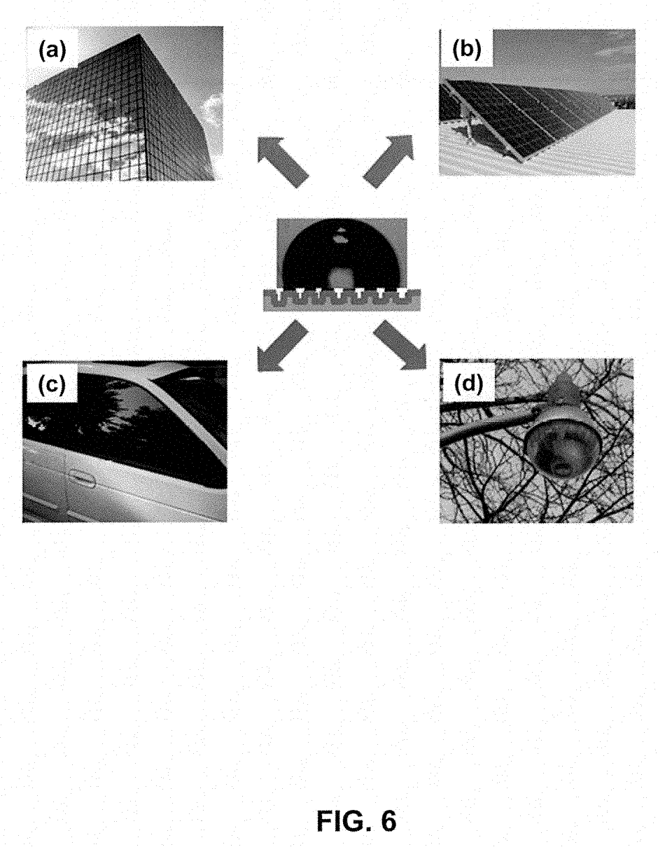

FIG. 5 shows for illustrative purposes only an example of creating a super-hydrophobic surface of one embodiment. FIG. 5A shows a water contact angle (CA) of <5° on a cleaning quartz substrate. FIG. 5B shows a CA of 80° after chemically modified with PS—OH monolayer. Moreover, FIG. 5C shows a CA of 110° on a PS—OH modified patterned quartz substrate using the method invented here. It shows that the CA has increased 40° after processing the substrate using the method invented here.

FIG. 6 shows a variety of potential applications using a super-hydrophobic surface proposed here: (a) building glass; (b) solar panels; (c) car windows; and (d) street light covers.

The foregoing has described the principles, embodiments and modes of operation of the present invention. However, the invention should not be construed as being limited to the particular embodiments discussed. The above described embodiments should be regarded as illustrative rather than restrictive, and it should be appreciated that variations may be made in those embodiments by workers skilled in the art without departing from the scope of the present invention as defined by the following claims.

What is claimed is:

1. A method of fabricating a super-hydrophobic surface, comprising:
using a self-assembly (SA) of a predetermined spherical or cylindrical block copolymer (BCP) film on a predetermined substrate to form a dot-array pattern at the nano-scale dimension;
removing the first block from BCP film and leaving the second block to form a dot-array pattern on a top of a chromium (Cr) hard mask layer;
etching the BCP dot-array pattern into the Cr layer and then into a substrate to form a nano-scale pillar array or a hole array using the plasma RIE etch;
using a self-assembled monolayer (SAMs) with a hydrophobic functional group to chemically modify the nano-scale pillar array or hole array.

2. The method of claim 1, further comprising depositing a hard mask layer including chromium (Cr) or carbon (C) on a substrate including at least one of silicon, quartz, or glass that can be chemically modified upon.

3. The method of claim 1, further comprising depositing a brush layer on the top of the hard mask layer.

4. The method of claim 1, further comprising using a predetermined spherical or cylindrical block copolymer (BCP) film on the brush layer to form a dot-array pattern at the nano-scale dimension.

5. The method of claim 1, further comprising a Cr etch process for spherical PS-b-PDMS block copolymer, or Cr dry liftoff process for cylindrical PS-b-PMMA block copolymer to generate Cr dot array pattern on the substrate.

6. The method of claim 3, further comprising using the PS—OH brush material for spherical PS-b-PDMS block copolymer. The brush layer thickness is at a range from 2 to 5 nm.

7. The method of claim 3, further comprising using a neutral brush material for cylindrical PS-b-PMMA block copolymer. Using a neutral brush material to chemically modify the substrate, the cylindrical PS-b-PMMA block copolymer can stand up.

8. The method of claim 3, further comprising using the PS—OH brush material that is deposited including using a spin-coating and including being annealed at 160° C. for 8 to 12 hours under vacuum and wherein the substrate is soaked in toluene for 30 minutes, and rinsed with isopropanol (IPA) and blow dried with N₂. The brush layer thickness is at a range from 2 to 5 nm.

9. The method of claim 1, further comprising a spherical PS-b-PDMS block copolymer (BCP) film that is deposited using spin-coating to a thickness of 15 to 30 nm and thermally annealed in a vacuum oven at a temperature range of 190 to 200° C. for 1 to 2 hours to reach their equilibrium state, wherein the PS-b-PDMS film is first treated by CF₄ for 7 to 10 sec to remove the top PDMS layer, and then the PS blocks are removed by O₂ RIE for 20 to 50 sec.

10. The method of claim 1, further comprising using plasma RIE including using chlorine (Cl₂) gas to etch PDMS spheres into the Cr hard mask layer to form Cr dot array pattern on the substrate. The Cr thickness is at a range of 2-4 nm, and the etch time is at a range of 20-60 sec.

11. The method of claim 1, further comprising using the piranha solution to clean the patterned substrate wherein the substrate is soaked in piranha solution at 120° C. for 1 hour, and rinsed with DI water and blow dried with N₂.

12. The method of claim 1, further comprising using a self-assembled monolayer (SAM) to chemically modify the patterned substrate. The SAM is required to have a hydrophobic functional group. The SAM is deposited including using a spin-coating and including being annealed at 160° C. for 12 hours under vacuum and wherein the substrate is soaked in toluene for 30 minutes, and rinsed with isopropanol (IPA) and blow dried with N₂.

13. An apparatus, comprising:
a first device configured to form a nano-scale dot array pattern using self-assembly of block copolymer (BCP);
a second device configured to transfer the BCP dot array pattern into the underneath Cr hard mask layer;
a third device configured to etch the Cr dot array pattern into a substrate to create a patterned substrate; and
a forth device configured to chemically modified the patterned substrate using self-assembled monolayer (SAM) with a hydrophobic functional group.

14. The apparatus of claim 13, further comprising a device to remove PS block from either the spherical PS-b-PDMS block copolymer or the cylindrical PS-b-PMMA block copolymer including using a reactive ion etching (RIE) including an oxygen gas (O₂) RIE.

15. The apparatus of claim 13, further comprising a device configured to etch the Cr dots into the substrate to fabricate a super-hydrophobic surface including using a RIE including a CF₄ RIE.

16. A structure, comprising:
a dot array polymer pattern is formed on substrate using self-assembly of block copolymer;
a dry chromium (Cr) etch device configured to be used by etching the BCP film into the Cr hard mask layer using Cl₂ RIE plasma etch; and
a plurality of Cr dot array pattern configured to etch the dot array pattern into a substrate to fabricate a super-hydrophobic surface.

17. The structure of claim 16, further comprising a brush material layer deposited on a substrate including silicon, quartz, and glass configured to be chemically modified upon and using a block copolymer (BCP) material including PS-b-PDMS or PS-b-PMMA, wherein the BCP material is spin coated and then thermally annealed.

18. The structure of claim 16, further comprising a brush configured to use a neutral layer material chemically neutral with respect to the cylindrical PS-b-PMMA block copolymer, whereas the PS—OH brush is used for spherical PS-b-PDMS block copolymer.

19. The structure of claim 16, further comprising using plasma RIE including using chlorine (Cl₂) gas to etch PDMS spheres into the Cr hard mask layer to form Cr dot array pattern on the substrate.

20. The structure of claim 16, further comprising etching the Cr dot array pattern into the substrate to fabricate a super-hydrophobic surface including using a RIE including a CF₄ RIE.
